(19) United States
(12) Patent Application Publication
(10) Pub. No.: US 2017/0062399 A1
(43) Pub. Date: Mar. 2, 2017

(54) METHOD AND STRUCTURE FOR LOW-K FACE-TO-FACE BONDED WAFER DICING

(71) Applicant: GLOBALFOUNDRIES Inc., Grand Cayman (KY)

(72) Inventors: Luke ENGLAND, Saratoga Springs, NY (US); Ramakanth ALAPATI, Rexford, NY (US)

(21) Appl. No.: 14/833,209

(22) Filed: Aug. 24, 2015

(51) Int. Cl. H01L 25/00; H01L 23/00; H01L 21/3105; H01L 23/48; H01L 21/311; H01L 21/268; H01L 25/065; H01L 21/82; H01L 21/768

(52) U.S. Cl. CPC H01L 25/50; H01L 21/82; H01L 24/94; H01L 21/31051; H01L 21/76802; H01L 21/76877; H01L 21/31116; H01L 21/268; H01L 21/76898; H01L 25/0657; H01L 23/481; H01L 24/83; H01L 24/11; H01L 24/17; H01L 2224/83896; H01L 2225/06541; H01L 2225/06548; H01L 2225/06517; H01L 2224/16227; H01L 2224/32145; H01L 2224/13025; H01L 2924/14

(57) ABSTRACT

Methods for removing low-k dielectric material from dicing lanes in a bonded pair of IC wafers and the resulting device are disclosed. Embodiments include providing low-k dielectric and standard dielectric layers on upper surfaces of top and bottom IC substrates, each including an array of adjacent IC die areas separated by dicing lanes; removing from the dicing lanes the standard and low-k dielectric layers to form cavities exposing sections of the upper surfaces of IC substrates; depositing a standard dielectric material in the cavities and on upper surfaces of the standard dielectric layer of the top and bottom IC substrates; planarizing upper surfaces of the standard dielectric material of the IC substrates; forming a face-to-face bonding of the IC substrates, wherein the dicing lanes in the IC substrates are vertically aligned; and dicing adjacent bonded IC die areas through vertically aligned dicing lanes in the IC substrates.

### TECHNICAL FIELD

The present disclosure relates generally to designing and fabricating integrated circuit (IC) devices. The present disclosure is particularly applicable to separating (e.g., dicing) adjacent IC areas/chips on a semiconductor wafer through a dicing lane between the IC chips, wherein the dicing lane may include low-k dielectric material.

### BACKGROUND

Generally, a plurality of devices/components (e.g., transistors, diodes, etc.) may be designed and embedded into an IC chip/die, which then may be placed into a package (e.g., plastic casing) or used as a bare die for placement onto a printed circuit board (PCB) of an electronic device. Due to limited space availability on the PCBs, some manufacturers of the IC chips are integrating multiple IC chips into 2.5-dimensional (2.5D) or 3D IC chip stacks offering a smaller footprint on a PCB. An IC chip stack may include several logic, memory, analog, or other chips, which may be connected to each other by using a through-silicon via (TSV) architecture. Typically, TSVs are vertical vias etched into a silicon layer and filled with a conducting material (e.g., copper (Cu)), to provide connectivity for transfer of electronic signals or power supply between the vertically stacked IC chips. In addition to traditional technology node scaling at the transistor level, 2.5D/3D IC chip stacking is increasingly being utilized to provide solutions for meeting performance, power, and bandwidth requirements of various electronic devices.

FIG. 1 schematically illustrates an example IC chip stack structure including a face-to-face (F2F) bonding of IC chips. As illustrated, the 3D IC chip stack includes IC chips 101 and 103 with TSVs 105 used to interconnect the 3D stack (e.g., IC chip 101), through an interconnection layer 107 (e.g., including solder balls, copper pillars, micro-bumps) to an IC package substrate 109. The IC package substrate 109 may include an interconnection layer 111 (e.g., including a solder ball grid array). As illustrated, the IC chips may include back-end-of-line (BEOL) metal layers including front metal layers 113 and a back metal layer 115, a device layer 117, and a silicon layer/IC substrate 119. A device layer 117 may include one or more dielectric layers for providing isolation between the devices. The F2F bonding of the IC chips 101 and 103 may be through metal vias connected to a final metal layer included in the front metal layers 113.

In a typical semiconductor manufacturing process, a semiconductor wafer includes an array of IC chips, which may be separated/diced through dicing lanes/scribe areas between the IC chips. Depending on dielectric layers and IC structures present in the dicing lanes, mechanical and/or laser dicing processes may be utilized. A 3D chip stack may be formed by F2F bonding of vertically aligned semiconductor wafers that include an array of IC chips on each wafer. After the bonding, bonded 3D IC chips can be separated from each other through dicing lanes between adjacent bonded IC chips. However, when dicing F2F bonded wafers with low-k dielectric material in the dicing lanes, a standard method of laser scribing to remove the low-k dielectric material before mechanical dicing of the IC chips cannot be used since the BEOL layers (e.g., dielectrics) are now sandwiched between the semiconductor wafers. Using only a mechanical dicing process to separate the bonded IC chips provides a high risk of cracking that may be initiated in the low-k dielectric layers and may propagate into the other layers leading to failures.

A need therefore exists for a methodology and structure enabling reliable mechanical dicing of low-K F2F bonded IC wafer stacks.

### SUMMARY

An aspect of the present disclosure is a method for enabling reliable mechanical dicing of low-K F2F bonded wafer stacks.

Another aspect of the present disclosure is a semiconductor structure enabling reliable mechanical dicing of low-K F2F bonded wafer stacks.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure some technical effects may be achieved in part by a method including providing a low-k dielectric layer and a standard dielectric layer, respectively, on upper surfaces of top and bottom IC substrates, each of the top and bottom IC substrates including an array of adjacent IC die areas separated by dicing lanes; removing from the dicing lanes the standard dielectric layer and the low-k dielectric layer, respectively, to form cavities exposing sections of the upper surfaces of the top and bottom IC substrates; depositing a standard dielectric material in the cavities and on upper surfaces of the standard dielectric layer of the top and bottom IC substrates; planarizing upper surfaces of the standard dielectric material of the top and bottom IC substrates; forming a face-to-face bonding of the top and bottom IC substrates, wherein the dicing lanes in the top and bottom IC substrates are vertically aligned; and dicing adjacent bonded IC die areas through vertically aligned dicing lanes in the top and bottom IC substrates.

Another aspect includes planarizing the upper surfaces of the standard dielectric material to a level of an upper surface of a final metal layer; and forming vias in the standard dielectric material in the IC die areas of the top and bottom IC substrates, wherein upper surfaces of the vias are at the level of the upper surface of the final metal layer. Some aspects include forming the final metal layer and the vias by a single or a dual damascene process.

One aspect includes removing the low-k dielectric layer by a dry etching process. Some aspects include removing the low-k dielectric layer, IC metal structures, or a combination thereof from the dicing lane by a laser beam.

In some aspects, a combined thickness of the standard dielectric layer and the standard dielectric material is more than the level of the upper surface of the final metal layer. In a further aspect, the dicing includes a mechanical dicing process.

In another aspect, prior to the dicing, the method includes removing a vertical portion of a lower surface of the bottom IC substrate in the face-to-face bonded top and bottom IC substrates to expose a section of each of through-silicon vias in the bottom IC substrate; and forming conducting elements between exposed sections of the through-silicon vias and interconnecting elements of a package substrate.

In some aspects, for the face-to-face bonding of the top and bottom IC substrates, exposed upper surfaces of vertically aligned vias in the top and bottom IC substrates being bonded to each other by oxide bonding.

Another aspect of the present disclosure includes a semiconductor device including: face-to-face vertically aligned and bonded top and bottom IC substrates including adjacent IC areas in each of the top and bottom IC substrates; a dicing lane in each of the top and bottom IC substrates separating the adjacent IC die areas in the top and bottom IC substrates; a low-k dielectric layer and a standard dielectric layer in the IC die areas of the top and bottom IC substrates, wherein the dicing lane in each of the top and bottom IC substrates substantially includes standard dielectric material.

In another aspect, the semiconductor device includes vias in the standard dielectric layer in the IC die areas of the top and bottom IC substrates, wherein upper surfaces of the vias are at a level of an upper surface of a final metal layer in each of the top and bottom IC substrates.

In some aspects, the semiconductor device includes exposed sections of through-silicon vias in a lower surface of the bottom IC substrate; and conducting elements between the exposed sections of the through-silicon vias and interconnecting elements of a package substrate.

In a further aspect, the face-to-face bonding of the top and bottom IC substrates includes exposed upper surfaces of vertically aligned vias in the top and bottom IC substrates being bonded to each other by oxide bonding.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates an example of an IC chip stack structure including face-to-face bonding of IC chips;

FIGS. 2A through 2D schematically illustrate a process flow for preparing IC chips for wafer bonding including dicing lanes, in accordance with exemplary embodiments;

FIGS. 2E through 2G schematically illustrate a process flow for dicing IC chip stacks including dicing lanes, in accordance with exemplary embodiments; and

FIG. 2H schematically illustrates IC chip stacks in an example IC packaging.

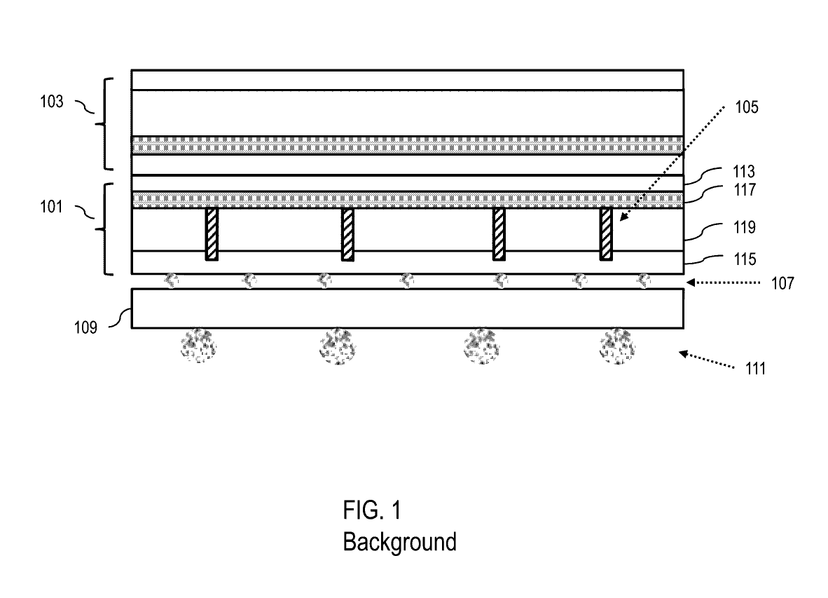

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the problem of cracking in low-k dielectric layers and propagating into other layers of IC chip stacks leading to failures attendant upon dicing of bonded IC chip stacks by using only a mechanical dicing process. The present disclosure addresses and solves such problems, for instance, by, inter alia, removing low-k dielectric material from dicing lanes in an IC chip stack and replacing the low-k with standard oxide or nitride dielectric material. Prior to F2F wafer bonding, dielectric layers in the dicing lanes are removed, for example, by using laser ablation or plasma etching, which creates a cavity/open scribe area. The cavity is then filled with a final top level standard oxide or nitride dielectric before planarization and F2F wafer bonding. The results allow for use of mechanical dicing methods alone for bonded wafer dicing.

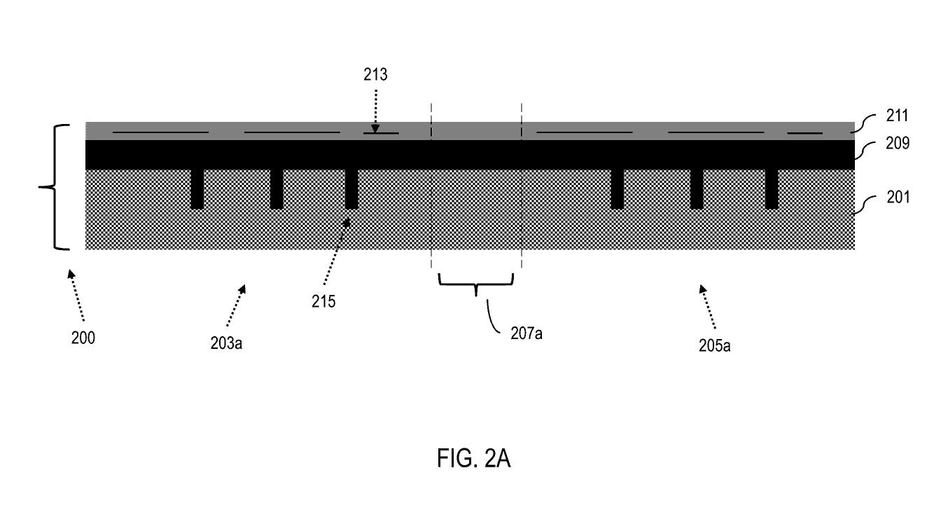

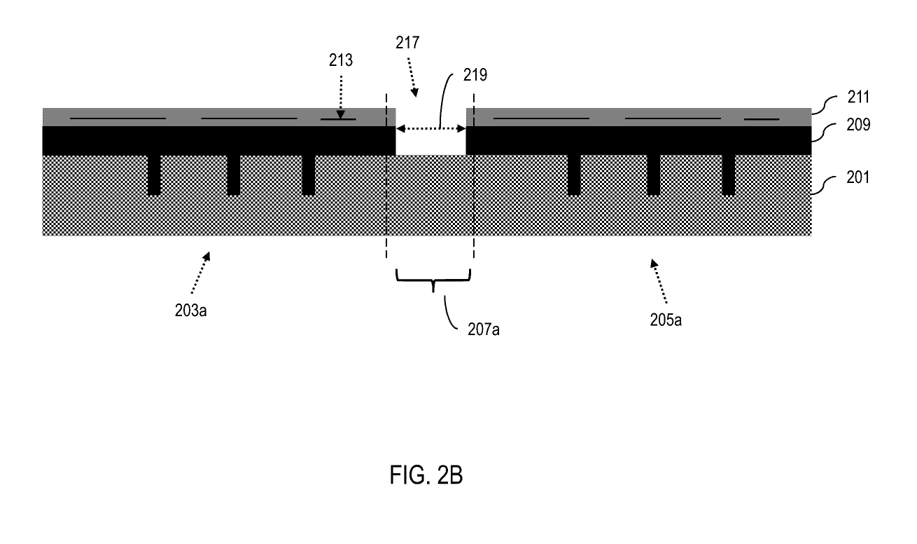

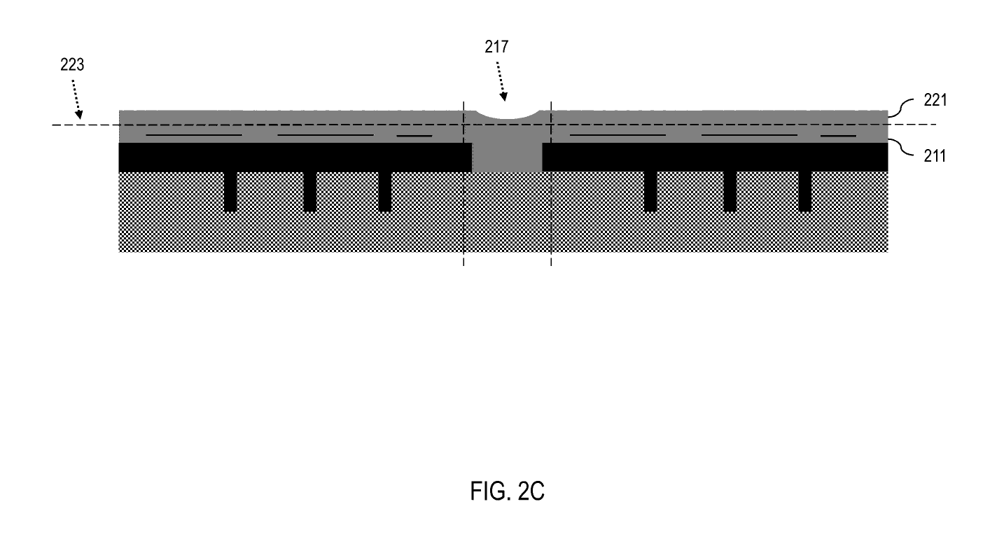

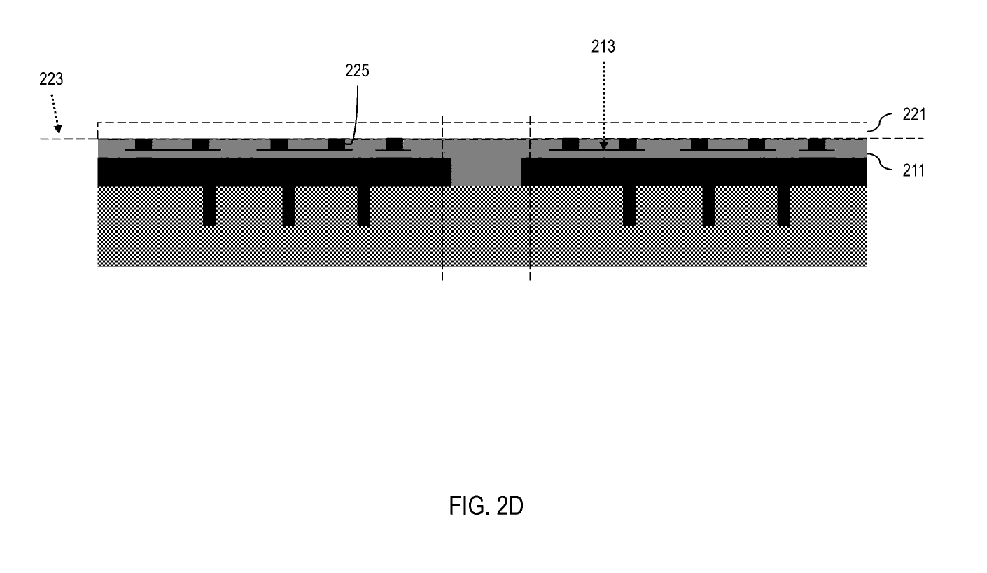

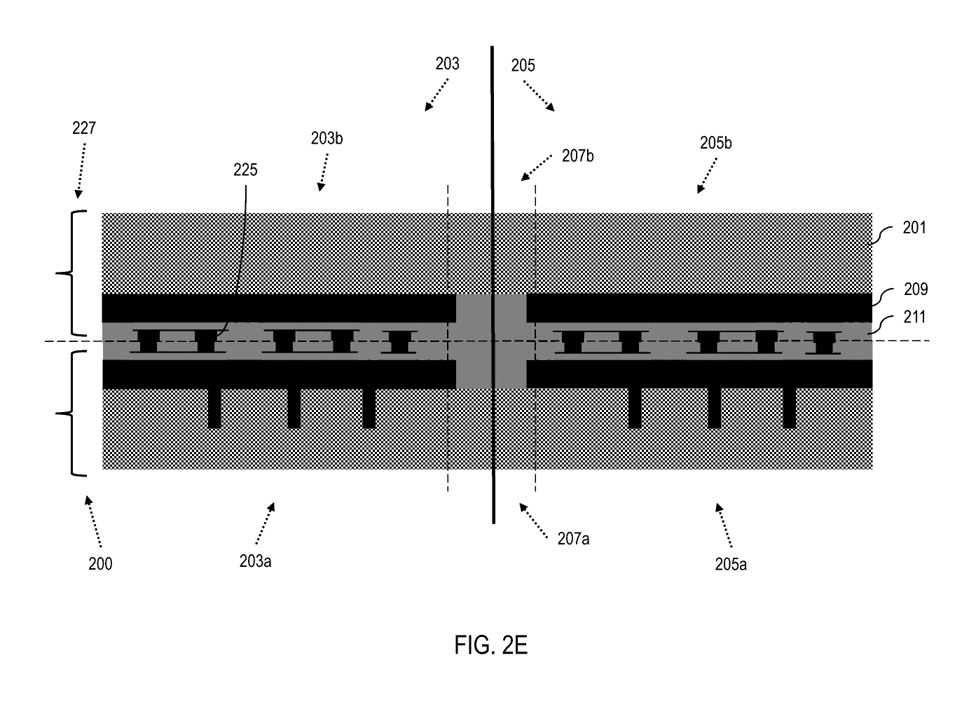

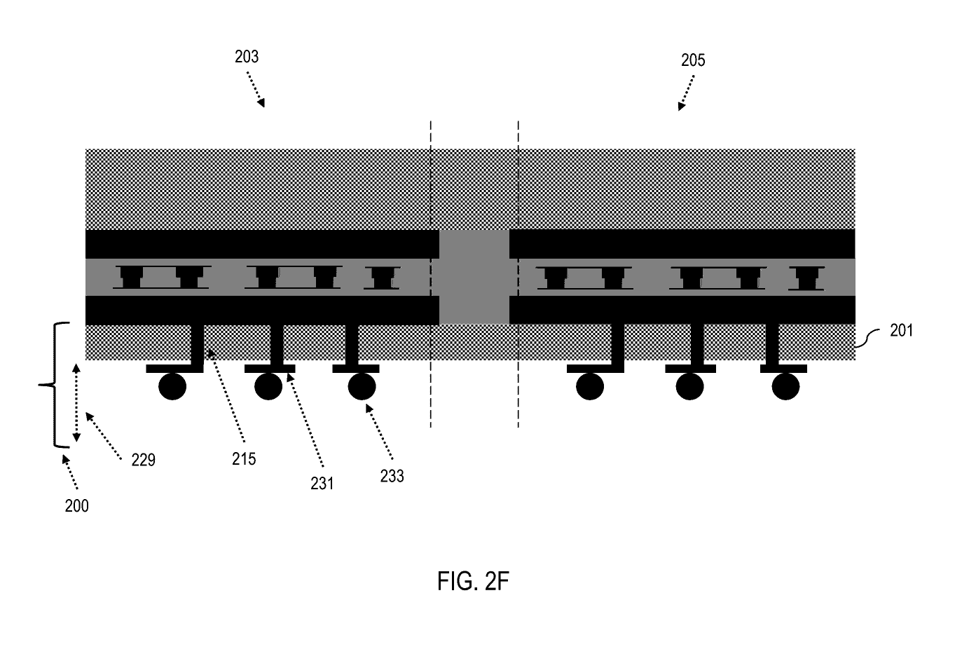

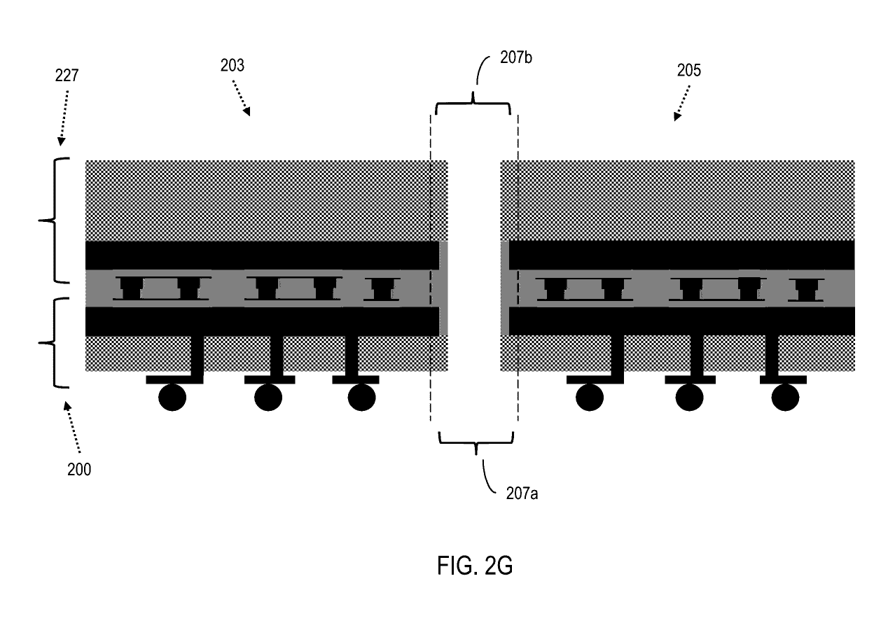

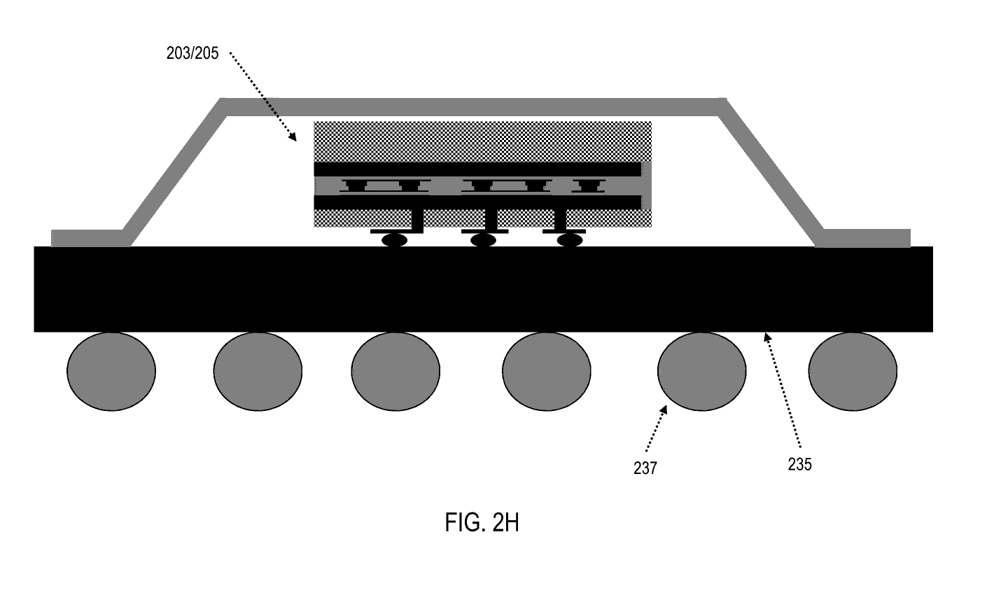

As noted earlier, a semiconductor wafer may include an array of IC chips, which, at some point in the manufacturing process, may be diced into individual IC chips. For illustration convenience, FIG. 2A illustrates an IC wafer 200 including substrate 201, two adjacent IC chips/areas 203a and 205a, and a dicing lane 207a between the two IC chips. Also illustrated are a low-k dielectric layer 209 on an upper surface of the IC substrate 201, and a standard dielectric layer 211 on an upper surface of the low-k dielectric layer 209. Additionally, the dielectric layers 209 and 211 may include BEOL IC connection elements/structures 213 (e.g., used for device testing). In some instances, the BEOL IC connection elements/structures 213 may be only in the dielectric layers 209 and 211 of the IC chips 203a and 205a. Furthermore, the substrate 201 includes a plurality of TSVs 215 for providing connectivity to another IC chip or an IC chip package substrate. The IC wafer 200 may be a bottom wafer in a bonded pair of IC wafers.

Adverting to FIG. 2B, a section of each of the standard dielectric layer 211 and the low-k dielectric layer 209, respectively, are removed from the dicing lane 207a to form a cavity 217, which exposes a section of the upper surface of the IC substrate 201 in the cavity 217. The width 219 of the cavity 217 may be based on one or more parameters associated with a dicing process (e.g., a mechanical saw) that may be utilized to separate the IC chips 203a and 205a. For example, a dry etching process may be utilized to remove the low-k dielectric layer 209 in the cavity 217. In a scenario when there are IC metal structures 213 in the dicing lane 207a, the low-k dielectric layer 209 may be removed by using a laser beam (e.g., ablation). However, an effective post laser cleaning process would be necessary for additional BEOL fabrication processes that may follow.

In FIG. 2C, an additional layer 221 of standard dielectric material (e.g., as in layer 211) is deposited into the cavity 217 and on an upper surface of the standard dielectric layer 211, wherein a combined thickness of the standard dielectric layer 211 and the standard dielectric material 221 is more than a thickness level 223 of a final metal layer. This is to ensure that the cavity 217 is sufficiently filled with the standard dielectric material 221 as well as to provide a sufficient margin for planarization of the standard dielectric material 221 down to the level 223 that, for example, may be required for a last BEOL metal layer, as illustrated in FIG. 2D. Additionally, as illustrated in FIG. 2D, metal (e.g., copper) vias 225 are formed in the standard dielectric material 211 and make contact with the IC elements 213, wherein upper surfaces of the vias 225 are at the level 223 of the upper surface of final metal layer. The final metal layer 223 and the vias 225 may be formed by a single or a dual damascene process.

Adverting to FIG. 2E, similar processes, as discussed with reference to FIGS. 2A through 2D, may be used to provide a top wafer 227 for a bonded pair of IC wafers, e.g., 200 and 227. As the bottom wafer 200, the top wafer 227 includes similar IC chips 203b and 205b that include a dicing lane 207b, layers of a low-k dielectric layer 209 on a lower surface of the IC substrate 201, and a standard dielectric layer 211 on a lower surface of the low-k dielectric layer 209. A F2F bonding of the IC wafers 200 and 227 are formed to result adjacent bonded IC chip stacks 203 (203a/203/b) and 205 (205a/205b), wherein the dicing lanes 207b and 207a in the top and bottom wafers 200 and 227 are vertically aligned. Also, exposed upper surfaces of vertically aligned vias 225 in the top and bottom IC wafers 200 and 227 may be bonded to each other. Furthermore, an oxide bonding process may be utilized for the F2F bonding of the top and bottom IC wafers 200 and 227.

In FIG. 2F, a vertical portion 229 of a lower surface of the IC substrate 201 in the bottom wafer 200 may be removed to expose TSVs 215, and conducting elements 231 may be formed between the exposed TSVs 215 and interconnecting elements 233 (e.g., solder bumps, for example of tin-silver (SnAg)) for connecting to an IC package substrate (as will be discussed in FIG. 2H). Adverting to FIG. 2G, the IC chip stacks 203 and 205 may be separated by use of a mechanical dicing device through the vertically aligned dicing lanes 207b and 207a in the top and bottom wafers 227 and 200. FIG. 2H illustrates a flip-chip IC package including an IC chip stack, e.g., 203 or 205, connected to a package substrate 235, which may be connected to a PCB of an electronic device through the interconnecting elements 237.

The embodiments of the present disclosure can achieve several technical effects including using standard equipment available in the semiconductor manufacturing industry to remove low-k dielectric material from dicing lanes in an IC wafer for preventing cracking during mechanical dicing of the bonded wafer stacks. Furthermore, the embodiments enjoy utility in various industrial applications as, for example, microprocessors, smart phones, mobile phones, cellular handsets, set-top boxes, DVD recorders and players, automotive navigation, printers and peripherals, networking and telecom equipment, gaming systems, digital cameras, or other devices utilizing logic or high-voltage technology nodes. The present disclosure therefore enjoys industrial applicability in any of various types of highly integrated semiconductor devices, including devices that use static-random-access memory (SRAM) cells (e.g., liquid crystal display (LCD) drivers, digital processors, etc.)

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a low-k dielectric layer and a standard dielectric layer, respectively, on upper surfaces of top and bottom integrated circuit (IC) substrates, each of the top and bottom IC substrates including an array of adjacent IC die areas separated by dicing lanes;
removing from the dicing lanes the standard dielectric layer and the low-k dielectric layer, respectively, to form cavities exposing sections of the upper surfaces of the top and bottom IC substrates;
depositing a standard dielectric material in the cavities and on upper surfaces of the standard dielectric layer of the top and bottom IC substrates;
planarizing upper surfaces of the standard dielectric material of the top and bottom IC substrates;
forming a face-to-face bonding of the top and bottom IC substrates, wherein the dicing lanes in the top and bottom IC substrates are vertically aligned; and
dicing adjacent bonded IC die areas through vertically aligned dicing lanes in the top and bottom IC substrates.

2. The method according to claim 1, further comprising:
planarizing the upper surfaces of the standard dielectric material to a level of an upper surface of a final metal layer; and
forming vias in the standard dielectric material in the IC die areas of the top and bottom IC substrates, wherein upper surfaces of the vias are at the level of the upper surface of the final metal layer.

3. The method according to claim 2, further comprising:
forming the final metal layer and the vias by a single or a dual damascene process.

4. The method according to claim 1, further comprising:
removing the low-k dielectric layer by a dry etching process.

5. The method according to claim 1, further comprising:
removing the low-k dielectric layer, IC metal structures, or a combination thereof from the dicing lane by a laser beam.

6. The method according to claim 2, wherein a combined thickness of the standard dielectric layer and the standard dielectric material is more than the level of the upper surface of the final metal layer.

7. The method according to claim 1, wherein the dicing includes a mechanical dicing process.

8. The method according to claim 1, further comprising:
prior to the dicing, removing a vertical portion of a lower surface of the bottom IC substrate in the face-to-face bonded top and bottom IC substrates to expose a section of each of through-silicon vias in the bottom IC substrate; and
forming conducting elements between exposed sections of the through-silicon vias and interconnecting elements of a package substrate.

9. The method according to claim 1, wherein face-to-face bonding of the top and bottom IC substrates comprises:
exposed upper surfaces of vertically aligned vias in the top and bottom IC substrates being bonded to each other by oxide bonding.

10. A semiconductor device comprising:
face-to-face vertically aligned and bonded top and bottom integrated circuit (IC) substrates including adjacent IC areas in each of the top and bottom IC substrates;
a dicing lane in each of the top and bottom IC substrates separating the adjacent IC die areas in the top and bottom IC substrates; and
a low-k dielectric layer and a standard dielectric layer in the IC die areas of the top and bottom IC substrates, wherein the dicing lane in each of the top and bottom IC substrates substantially includes standard dielectric material.

11. The semiconductor device according to claim 10, further comprising:
vias in the standard dielectric layer in the IC die areas of the top and bottom IC substrates, wherein upper surfaces of the vias are at a level of an upper surface of a final metal layer in each of the top and bottom IC substrates.

12. The semiconductor device according to claim 10, further comprising:
exposed sections of through-silicon vias in a lower surface of the bottom IC substrate; and
conducting elements between the exposed sections of the through-silicon vias and interconnecting elements of a package substrate.

13. The semiconductor device according to claim 10, wherein face-to-face bonding of the top and bottom IC substrates comprises:
exposed upper surfaces of vertically aligned vias in the top and bottom IC substrates being bonded to each other by oxide bonding.

14. A method comprising:
providing a low-k dielectric layer and a standard dielectric layer, respectively, on upper surfaces of top and bottom integrated circuit (IC) substrates, each of the top and bottom IC substrates including an array of adjacent IC die areas separated by dicing lanes;
removing from the dicing lanes the standard dielectric layer and the low-k dielectric layer, respectively, to form cavities exposing sections of the upper surfaces of the top and bottom IC substrates;
depositing a standard dielectric material in the cavities and on upper surfaces of the standard dielectric layer of the top and bottom IC substrates;
planarizing upper surfaces of the standard dielectric material of the top and bottom IC substrates to a level of an upper surface of a final metal layer;
forming a face-to-face bonding of the top and bottom IC substrates, wherein the dicing lanes in the top and bottom IC substrates are vertically aligned; and
dicing, by using a mechanical dicing process, adjacent bonded IC die areas through vertically aligned dicing lanes in the top and bottom IC substrates.

15. The method according to claim 14, further comprising:
forming vias in the standard dielectric material in the IC die areas of the top and bottom IC substrates, wherein upper surfaces of the vias are at the level of the upper surface of the final metal layer; and
forming the final metal layer and the vias by a single or a dual damascene process.

16. The method according to claim 14, further comprising:
removing the low-k dielectric layer by a dry etching process.

17. The method according to claim 14, further comprising:
removing the low-k dielectric layer, IC metal structures, or a combination thereof from the dicing lane.

18. The method according to claim 14, wherein a combined thickness of the standard dielectric layer and the standard dielectric material is more than the level of the upper surface of the final metal layer.

19. The method according to claim 14, further comprising:
prior to the dicing, removing a vertical portion of a lower surface of the bottom IC substrate in the face-to-face bonded top and bottom IC substrates to expose a section of each of through-silicon vias in the bottom IC substrate; and
forming conducting elements between exposed sections of the through-silicon vias and interconnecting elements of a package substrate.

20. The method according to claim 14, wherein face-to-face bonding of the top and bottom IC substrates comprises:
exposed upper surfaces of vertically aligned vias in the top and bottom IC substrates being bonded to each other by oxide bonding.
